(19) United States
(12) Patent Application Publication
(10) Pub. No.: US 2024/0222563 A1
(43) Pub. Date: Jul. 4, 2024

(54) LIGHT-EMITTING ELEMENT AND LIGHT-EMITTING DEVICE

(71) Applicant: Tianjin Sanan Optoelectronics Co., Ltd., Tianjin (CN)

(72) Inventors: Zhiwei WU, Tianjin (CN); Yanyun WANG, Tianjin (CN); Weiping XIONG, Tianjin (CN); Di GAO, Tianjin (CN); Huanshao KUO, Tianjin (CN); Yuren PENG, Tianjin (CN)

(73) Assignee: Tianjin Sanan Optoelectronics Co., Ltd., Tianjin (CN)

(21) Appl. No.: 18/533,122

(22) Filed: Dec. 7, 2023

(30) Foreign Application Priority Data
Dec. 28, 2022 (CN) 202211693520.6

(51) Int. Cl. H01L 33/38; H01L 33/62

(52) U.S. Cl. CPC H01L 33/387; H01L 33/62

(57) ABSTRACT

A light-emitting element and a light-emitting device are provided. The light-emitting element includes an epitaxial layer, an insulating layer formed on a surface of the epitaxial layer, and an electrode structure. The electrode structure includes a first electrode connected to a first conductivity type semiconductor layer and a second electrode connected to a second conductivity type semiconductor layer. The electrode structure includes a wiring portion and a connecting portion. The wiring portion is located above the insulating layer. The connecting portion penetrates through the insulating layer from an edge of the wiring portion and extends towards the epitaxial layer. The connecting portion is arranged to extend from the edge of the wiring portion towards the epitaxial layer. Further, a projection of the wiring portion on a front surface of the substrate does not overlap a projection of the connecting portion on the front surface of the substrate.

### CROSS-REFERENCE TO RELATED APPLICATION

This application claims the priority benefit of China application serial no. 202211693520.6, filed on Dec. 28, 2022. The entirety of the above-mentioned patent application is hereby incorporated by reference herein and made a part of this specification.

### BACKGROUND

### Technical Field

The disclosure relates to the technical field of semiconductor devices, and in particular, to a light-emitting element and a light-emitting device.

### Description of Related Art

LEDs are widely used in the lighting industry due to their advantages such as high brightness and low energy consumption. For a horizontally-structured light-emitting element, the wiring structure is an important structure that affects its optical and electrical properties. The main factors that affect the reliability of the wiring are: (1) the flatness of the surface of the wiring portion; and (2) the effective dispersion of the impact force during the wiring process. The factors that affect its light extraction efficiency mainly include: (1) the shielding used for packaging wiring electrodes; (2) reflection at the interfaces of materials with different refractive indexes during the light output process; and (3) the absorption of light by various materials during the light output process.

In view of the abovementioned defects of LEDs, it is necessary to provide a solution that can effectively improve the wiring reliability of LEDs and improve their light emission efficiency.

### SUMMARY

In view of the abovementioned defects of LEDs in the related art, the disclosure provides a light-emitting element and a light-emitting device to solve one or more of the above problems.

An embodiment of the disclosure provides a light-emitting element including an epitaxial layer, an insulating layer, and an electrode structure.

The epitaxial layer at least includes a first conductivity type semiconductor layer, an active layer, and a second conductivity type semiconductor layer stacked in sequence. The epitaxial layer is formed with a first mesa, and the first mesa exposes the first conductivity type semiconductor layer.

The insulating layer is formed on the epitaxial layer and has a through hole.

The electrode structure includes a first electrode connected to the first conductivity type semiconductor layer and a second electrode connected to the second conductivity type semiconductor layer.

The electrode structure includes a wiring portion and at least one connecting portion.

The wiring portion is located above the insulating layer, and the at least one connecting portion is located at an edge of the wiring portion, penetrates through the through hole of the insulating layer, and extends towards the epitaxial layer.

Optionally, a horizontal projected area of the wiring portion on the epitaxial layer is greater than a horizontal projected area of the at least one connecting portion on the epitaxial layer.

Optionally, a horizontal projection of the wiring portion on the epitaxial layer does not overlap a horizontal projection of the at least one connecting portion on the epitaxial layer.

Optionally, the insulating layer is an insulating reflective layer, and the insulating reflective layer is a single-layer structure or a multi-layer structure formed by two layers of materials being repeatedly stacked.

Optionally, a horizontal projected area of each electrode structure on the epitaxial layer accounts for 1% to 30% of a horizontal projected area of the epitaxial layer.

Optionally, current spreading layers connected to the at least one connecting portion are also formed above the epitaxial layer. The current spreading layers are linearly distributed above the epitaxial layer. A horizontal projection of each of the current spreading layers on the epitaxial layer does not overlap a horizontal projection of the wiring portion on the epitaxial layer.

Optionally, the light-emitting element further includes a bonding layer and a substrate. The bonding layer is formed between the substrate and the epitaxial layer for bonding the epitaxial layer to the substrate, and the substrate is a transparent substrate.

Optionally, a width of the wiring portion of the electrode structure is between 50 μm and 100 μm. A width of the at least one connecting portion is less than the width of the wiring portion. A width of the through hole of the insulating layer is 4 μm to 20 μm. The width of the at least one connecting portion is 2 μm to 10 μm larger than the width of the through hole of the insulating layer.

Optionally, a projection of the wiring portion on the epitaxial layer is circular, and a projection of the at least one connecting portion of the second electrode on the epitaxial layer is arc-shaped. The at least one connecting portion of the second electrode is located at the edge of the wiring portion.

Optionally, an ohmic contact layer is also formed on the second conductivity type semiconductor layer. The ohmic contact layer is located below the current spreading layers and does not overlap the wiring portion of the second electrode.

Optionally, the ohmic contact layer does not overlap the at least one connecting portion of the second electrode.

Optionally, an ohmic contact layer is also formed on the second conductivity type semiconductor layer. The ohmic contact layer is located below the current spreading layers and does not overlap the at least one connecting portion of the second electrode.

Optionally, the ohmic contact layer has a strip structure, and a length of the ohmic contact layer is less than a length of each of the current spreading layers.

Another embodiment of the disclosure further provides a light-emitting device including a die-bonding substrate and a light-emitting element fixed to the die-bonding substrate, and the light-emitting element is the light-emitting element provided by the disclosure.

As described above, the light-emitting element and the light-emitting device provided by the disclosure exhibit the following beneficial effects.

The light-emitting element provided by the disclosure includes the substrate, the epitaxial layer located on the front surface of the substrate, the insulating layer formed on the surface of the epitaxial layer, and the electrode structure. The electrode structure includes the first electrode connected to the first conductivity type semiconductor layer and the second electrode connected to the second conductivity type semiconductor layer. The electrode structure includes the wiring portion and the connecting portion. The wiring portion is located above the insulating layer, and the connecting portion penetrates through the insulating layer from the edge of the wiring portion and extends towards the epitaxial layer. The connecting portion of the electrode structure is arranged to extend from the edge of the wiring portion towards the epitaxial layer. Further, the projection of the wiring portion on the front surface of the substrate does not overlap the projection of the connecting portion on the front surface of the substrate. This design ensures that the entire wiring portion is located above the insulating layer, so that the surface of the wiring portion is flat, and the reliability of the chip wiring process is improved. Further, the wiring portion is arranged above the insulating layer. The hardness of the insulating layer is relatively high, so the impact force during wiring can be effectively dispersed, and chip reliability is therefore improved.

The insulating layer provided by the disclosure can preferably be an insulating reflective layer, such as a DBR reflective layer. Herein, the wiring portion of the metal material and the insulating reflective layer form an ODR structure. In this way, the reflection of the light emitted by the epitaxial layer can be increased, the light extraction efficiency of the light-emitting element can be improved, and the brightness of the light-emitting element can be enhanced.

In the light-emitting device provided by the disclosure, a transparent die-bonding adhesive with a certain refractive index is used to fix the light-emitting element to the die-bonding substrate, so that more light is emitted from the chip and reflected through the die-bonding substrate with a reflective mirror. In this way, the external quantum efficiency of the chip is improved, and the light emission efficiency of the light-emitting device is enhanced.

### BRIEF DESCRIPTION OF THE DRAWINGS

FIG. 1 is a schematic structural diagram of a light-emitting element according to Embodiment One of the disclosure.

FIG. 2 is a schematic top structural view of the light-emitting element shown in FIG. 1.

FIG. 3 is a schematic structural diagram of the light-emitting element according to Embodiment Two.

FIG. 4 is a schematic top structural view of the light-emitting element shown in FIG. 3.

FIG. 5 is a schematic structural diagram of a light-emitting device according to Embodiment Three of the disclosure.

### DESCRIPTION OF THE EMBODIMENTS

The implementation of the disclosure is illustrated below by specific embodiments. A person having ordinary skill in the art can easily understand other advantages and effects of the disclosure from the content disclosed in this specification. The disclosure can also be implemented or applied through other different specific implementation ways. The details in this specification can also be modified or changed based on different viewpoints and applications without departing from the spirit of the disclosure.

### Embodiment One

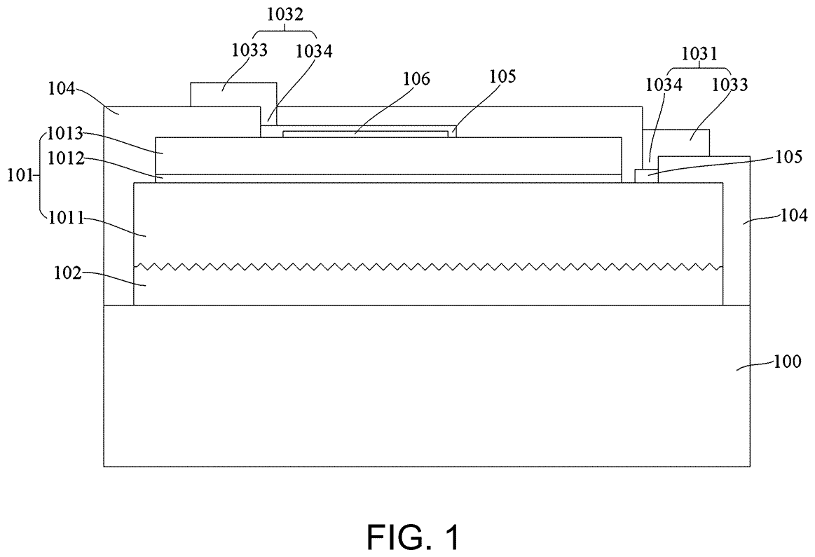

This embodiment provides a light-emitting element. As shown in FIG. 1, the light-emitting element provided by this embodiment includes a substrate 100, and the substrate 100 has a front surface and a back surface opposite to each other. The front surface of the substrate 100 is formed with an epitaxial layer 101, and the epitaxial layer 101 includes a first conductivity type semiconductor layer 1011, an active layer 1012, and a second conductivity type semiconductor layer 1013 stacked in sequence on the front surface of the substrate 100. Optionally, the substrate 100 may be a sapphire substrate or a transparent substrate that is suitable for bonding the epitaxial layer 101 and does not affect the light emission of the light-emitting element.

The epitaxial layer 101 may be an AlGaInP series material layer or a quaternary epitaxial layer and can radiate red light when being powered. Preferably, the first conductivity type semiconductor layer 1011 may be a P-type layer, and the second conductivity type semiconductor layer 1013 may be an N-type layer. The epitaxial layer 101 is bonded to the substrate 100 through a bonding layer 102. Preferably, a side of the epitaxial layer 101 facing the substrate 100 is formed into a rough surface to reduce the number of reflections during light output and to improve the brightness of the light-emitting element.

For instance, a growth substrate is provided first. The second conductivity type semiconductor layer 1013, the active layer 1012, and the first conductivity type semiconductor layer 1011 are grown in sequence on the growth substrate, and the bonding layer 102 is then formed above the first conductivity type semiconductor layer 1011. The epitaxial layer 101 is bonded to the substrate 100 through the bonding layer 102, and then the growth substrate is removed.

Also as shown in FIG. 1, a mesa is formed in the epitaxial layer 101, and the mesa exposes the first conductivity type semiconductor layer 1011 for subsequent formation of an electrode structure. A side wall of the epitaxial layer 101 is formed with an insulating layer 104. To be specific, the insulating layer 104 is formed on a surface of the second conductivity type semiconductor layer 1013 of the epitaxial layer 101, a surface of the first conductivity type semiconductor layer 1011 exposed by a first mesa, and the exposed side wall of the epitaxial layer 101. The insulating layer 104 is used to protect the epitaxial layer 101 from being damaged by external water vapor or pollutants, and ensures the optical and electrical performance of the epitaxial layer 101. Preferably, the insulating layer 104 may be a single layer with a refractive index lower than that of the epitaxial layer 101 and capable of reflecting light, such as a SiO₂ layer or a SiNx layer. Alternatively, the insulating layer 104 may be multi-layered, such as two layers formed by a SiO₂ layer and a SiNx layer, or may be a multi-layered structure in which SiO₂ and TiO₂ are stacked in an alternating manner. The insulating layer 104 is formed as a reflective structural layer to reflect the light radiated by the active layer 1012 of the epitaxial layer 101 to improve the light extraction efficiency of the light-emitting element.

The insulating layer 104 has at least two through holes, each through hole has a width of 4 μm to 20 m, and a shape of the through hole may be circular or elliptical.

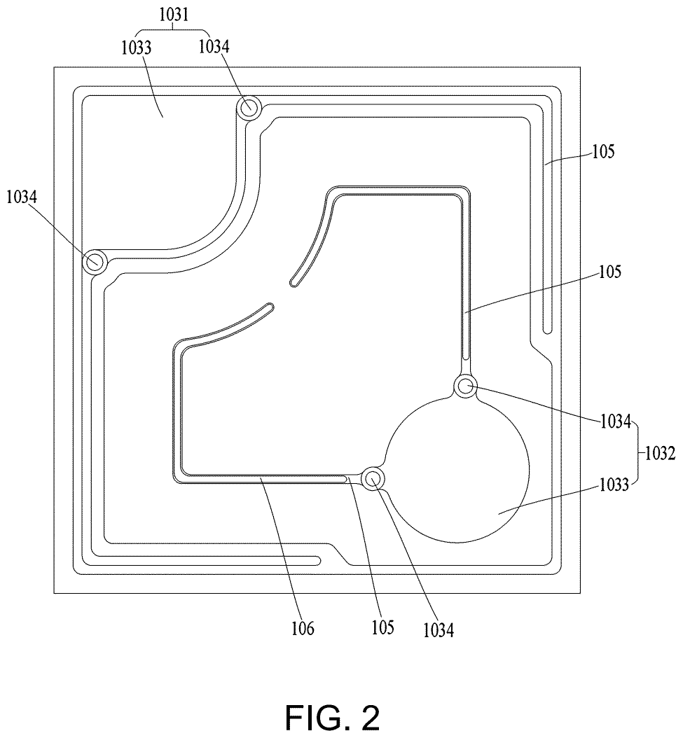

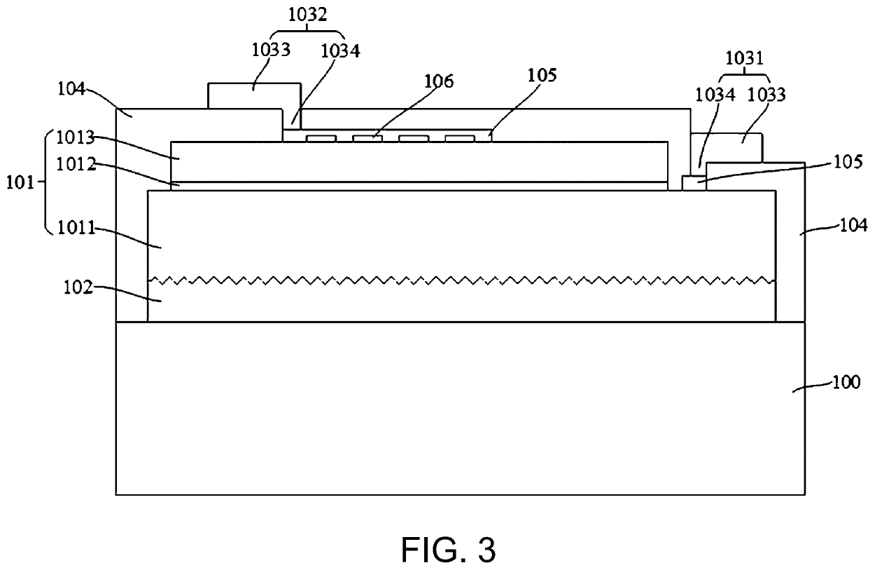

As shown in FIG. 1 to FIG. 2, an electrode structure is formed above the epitaxial layer 101. The electrode structure includes a first electrode 1031 and a second electrode 1032. The first electrode 1031 is formed on the first mesa, that is, above the first conductivity type semiconductor layer 1011, and the first electrode 1031 and the first conductivity type semiconductor layer 1011 are electrically connected. The second electrode 1032 is formed above the second conductivity type semiconductor layer 1013 and is electrically connected to the second conductivity type semiconductor layer 1013. With reference to FIG. 2, each of the first electrode 1031 and the second electrode 1032 includes a wiring portion 1033 and connecting portions 1034. The wiring portion 1033 is formed above the insulating layer 104, preferably at a corner position of the light-emitting element. The connecting portions 1034 extend downwards from an edge of the wiring portion 1033 and penetrate through the through holes of the insulating layer 104 until they are connected to the first conductivity type semiconductor layer 1011 or the second conductivity type semiconductor layer 1013. As shown in FIG. 3, a horizontal projected area of each wiring portion 1033 on the front surface of the substrate 100 (i.e., on the epitaxial layer 101) is greater than a horizontal projected area of each connecting portion 1034 on the front surface of the substrate 100. Further, a horizontal projection of each wiring portion 1033 on the front surface of the substrate 100 does not overlap a horizontal projection of each connecting portion 1034 on the front surface of the substrate 100. Preferably, the horizontal projection of each wiring portion 1033 on the front surface of the substrate 100 is circular. For instance, the wiring portion 1033 of the first electrode 1031 is formed in a circular structure on the surface of the epitaxial layer 101, or as shown in FIG. 2, at least two adjacent right-angled sides of the wiring portion 1033 of the first electrode 1031 are connected to one arc-shaped side. More preferably, two adjacent right-angled sides may be parallel to two edges of a rectangular chip. For instance, the horizontal projection of the wiring portion 1033 of the second electrode 1032 on the front surface of the substrate 100 is a circular structure.

A width of the wiring portion 1033 of each of the first electrode 1031 and the second electrode 1032 is between 50 μm and 100 μm. Reasonable design may be made according to different wiring needs.

Preferably, the connecting portions 1034 penetrate through the through holes of the insulating layer 104. A shape of the connecting portions 1034 may be similar to a shape of the through holes of the insulating layer 104, such as an arc shape. A size of the connecting portions 1034 may be slightly greater than a size of the through holes of the insulating layer 104, the connecting portions at least cover the through holes of the insulating layer 104, and penetrate through the through holes of the insulating layer 104. For example, a width of the connection portions 1034 is 2 μm to 10 μm greater than the width of the through holes.

It can be seen from FIG. 1 that the through holes of the insulating layer 104 are also located on one side of the wiring portions.

Since the connecting portions 1034 extend downwards from the edges of the wiring portions 1033 and do not overlap the wiring portions 1033, surfaces of the wiring portions 1033 are formed to be flat. This is beneficial to the improvement of the reliability of the wiring portions 1033 during the wiring process, and the electrical performance of the light-emitting element is also ensured. Further, the wiring portions 1033 are formed above the insulating layer 104. Since the insulating layer 104 has a high hardness, the insulating layer 104 can effectively disperse the impact force during wire bonding, so that the reliability of the electrode structure is improved. Besides, as described above, the insulating layer 104 may also be formed into a reflective structure, and the metal forming the electrode structure is formed above the insulating layer 104. Therefore, the electrode structure and the insulating layer 104 may form an ODR structure to increase reflection of light radiated from the active layer 1012. In this way, a light extraction rate of the light-emitting element is improved, and that the brightness of the light-emitting element is improved.

In an optional embodiment, a projected area of the electrode structure on the front surface of the substrate 100 accounts for 1% to 30% of a projected area of the epitaxial layer 101 on the front surface of the substrate 100. Compared to a flip-chip structure, an area ratio of the electrode structure is greatly reduced in the formal electrode structure. Further, as described above, the electrode structure and the insulating layer 104 form an ODR structure, so the reflection of light is increased.

In addition, as shown in FIG. 1 and FIG. 2, in this embodiment, the light-emitting element further includes current spreading layers 105. The current spreading layers 105 are formed above the first conductivity type semiconductor layer 1011 and above the second conductivity type semiconductor layer 1013. Further, the connecting portions 1034 of the electrode structure are formed above the current spreading layers 105 and are connected to the current spreading layers 105. Preferably, as shown in FIG. 2, the current spreading layers 105 are distributed in a linear structure above the epitaxial layer 101. The current spreading layers 105 are beneficial to the lateral spreading of current and improves the electrical performance of the light-emitting element.

The current spreading layers 105 are connected to the first electrode 1031 and the second electrode 1032, respectively. The number of the current spreading layers 105 connected to the first electrode 1031 may be one or more, and the number of the current spreading layers 105 connected to the second electrode 1032 may also be one or more. As shown in FIG. 2, the number of connecting portions 1034 is shown to be two, and the number of current spreading layers 105 above the epitaxial layer 101 corresponds to the number of connecting portions 1034. That is, the bottom of each of the connection portions 1034 contacts one end of one linear current spreading layer 105.

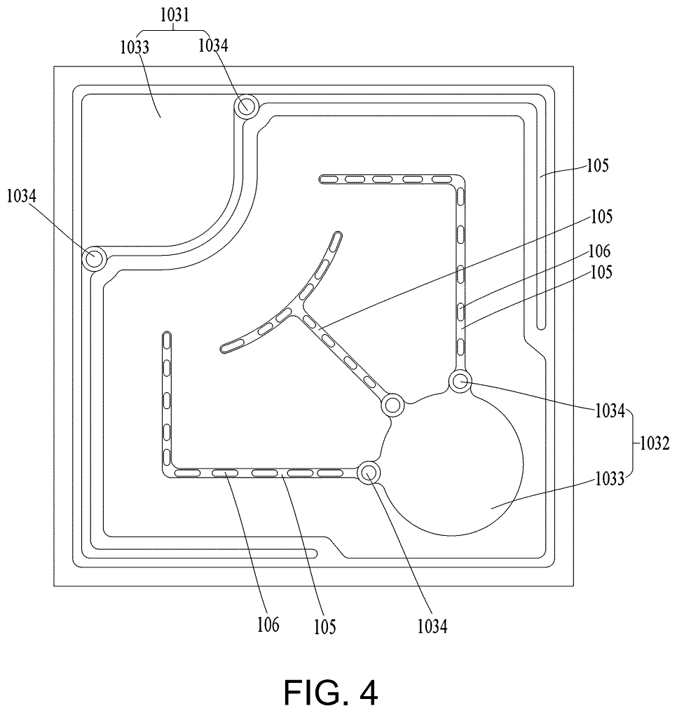

In another optional implementation of this embodiment, with reference to FIG. 4, herein, in the electrode structure, taking the second electrode 1032 as an example, the second electrode 1032 includes the wiring portion 1033 and three connecting portions 1034 extending downwards from an edge of the wiring portion 1033. The wiring portion 1033 is preferably located at the corner of the light-emitting element, and the three connecting portions 1034 are evenly distributed on a side away from the corner of the light-emitting element. Three portions of current spreading layers 105 are formed above the second conductivity type semiconductor layer 1013 and are respectively connected to the three connecting portions 1034.

The wiring portions 1033 of the first electrode 1031 and the second electrode 1032 are made of the same material including multiple layers of metal, and the multiple layers of metal at least include an adhesion layer (not shown) and a wiring layer (not shown). The adhesion layer is Ti or Cr, and a thickness thereof is 2.5 nm to 10 nm or thicker, 10 nm to 20 nm or thicker, or 20 nm to 50 nm, and the wiring layer may be Au with a thickness of 1 μm to 4 μm. Each of the wiring portions 1033 may also include an intermediate layer (e.g., a Pt layer, not shown) between the adhesion layer and the wiring layer, to act as a barrier. If the adhesion layer is thinner, it can reflect light to a certain extent through the intermediate layer or the wiring layer. In this way, the reflection effect of a wiring electrode is improved, and the brightness is thereby enhanced.

The connecting portions 1034 of the first electrode 1031 and the second electrode 1032 may be made of the same material as the wiring portions 1033 and may be formed by the same process steps. Further, the two are connected and include the same multiple layers of material. The difference between the wiring portions 1033 and the connecting portions 1034 of the electrode structure lies in different positions and different functions.

The current spreading layers 105 of the first electrode 1031 and the second electrode 1032 are formed by multiple layers of metal, and both include metal ohmic contact layers (not shown). When the first electrode 1031 is a P-type electrode, its metal ohmic contact layer may include a layer formed by a combination two elements, AuBe or AuZn, and may also include a protective layer (not shown) formed on the metal ohmic contact layer. The protective layer may be Pt to prevent the diffusion of metal elements in the metal ohmic contact layer. When the second electrode 1032 is an N-type electrode, its metal ohmic contact layer may include a layer formed by a combination of three elements, AuGeNi, and may also include a protective layer. The protective layer may be Pt to prevent the diffusion of metal elements in the metal ohmic contact layer. Certainly, each of the current spreading layers 105 may not include a protective layer. A preferred width of each of the current spreading layers may be 3 μm to 8 μm.

Optionally, an ohmic contact layer 106 may also be formed below the current spreading layer 105 connected to the second electrode 1032. In order to achieve a good ohmic contact effect between the semiconductor layer (second conductivity type semiconductor layer) and the current spreading layer 105, the ohmic contact layer 106 is formed above the second conductivity type semiconductor layer 1013. The ohmic contact layer 106 may be linear in shape and is located below the current spreading layer 105. A length of the ohmic contact layer 106 may be equal to or less than that of the current spreading layer 105, and a width of the ohmic contact layer 106 may be equal to or greater than the width of the current spreading layer 105. For instance, the width of the ohmic contact layer 106 may be 3 μm to 9 μm. As a better implementation, as shown in FIG. 2, the ohmic contact layer 106 is not located below the through holes of the insulating layer 104. A certain distance is provided between one end of the linear ohmic contact layer 106 and the through holes of the insulating layer 104. Optionally, the other end of the ohmic contact layer 106 is aligned with one end of the current spreading layer 105. Optionally, for instance, when the second electrode 1032 is an N-type electrode, the ohmic contact layer 106 may be gallium arsenide doped to be N-type.

### Embodiment Two

This embodiment also provides a light-emitting element, which is different from the light-emitting element provided in Embodiment One in that:

As shown in FIG. 3 and FIG. 4, the ohmic contact layer 106 is formed into a plurality of block structures distributed along a linear line. In this way, it can be more conducive to current spreading, an area of the ohmic contact layer 106 may be reduced, and the light absorption problem caused by doping gallium arsenide into N-type may be addressed.

When the ohmic contact layer 106 has multiple block structures, the widths of two adjacent block structures are the same or different, and/or the spacings are the same or different, which may be adjusted according to actual needs.

### Embodiment Three

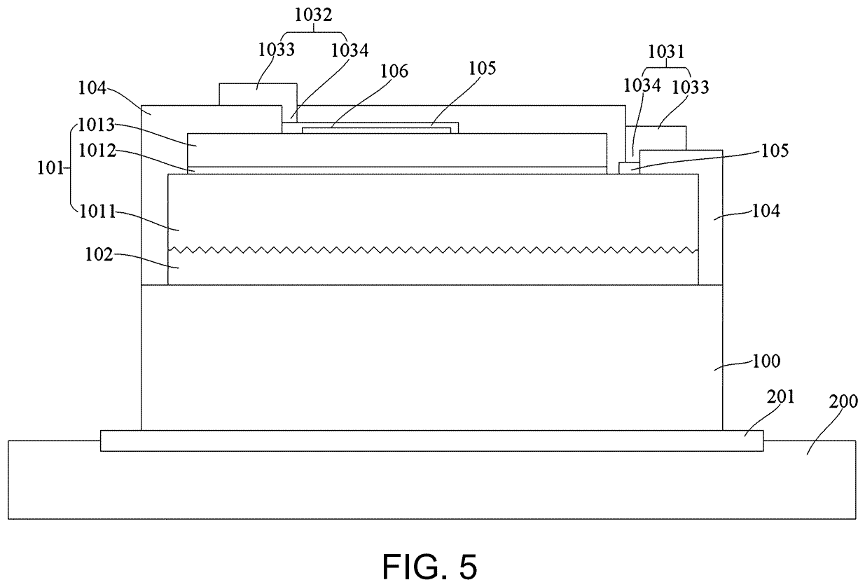

This embodiment provides a light-emitting device. As shown in FIG. 5, the light-emitting device includes a die-bonding substrate 200 and a light-emitting element located above the die-bonding substrate 200. The light-emitting element may be the light-emitting element provided in Embodiment One and/or Embodiment Two of the disclosure. The die-bonding substrate 200 may be a ceramic substrate, a printed circuit board, etc. A die-bonding region is provided above the die-bonding substrate 200, and the light-emitting element is fixed to the die-bonding region. For instance, the light-emitting element is fixed to the die-bonding substrate 200 through a die-bonding adhesive 201 with a specific refractive index. Therefore, the die-bonding adhesive 201 may further reflect the light emitted by the light-emitting element, so that the light emission efficiency of the light-emitting device is improved.

The above-mentioned embodiments only illustrate the principles and effects of the disclosure, but are not intended to limit the disclosure. A person having ordinary skill in the art can modify or change the abovementioned embodiments without departing from the spirit and scope of the disclosure. Therefore, all equivalent modifications or changes made by a person having ordinary skill in the art without departing from the spirit and technical ideas disclosed in the disclosure shall still be covered by the claims of the disclosure.

What is claimed is:

1. A light-emitting element, comprising:
an epitaxial layer at least comprising a first conductivity type semiconductor layer, an active layer, and a second conductivity type semiconductor layer stacked in sequence, wherein the epitaxial layer is formed with a first mesa, and the first mesa exposes the first conductivity type semiconductor layer;
an insulating layer formed on the epitaxial layer and having a through hole; and
an electrode structure comprising a first electrode connected to the first conductivity type semiconductor layer and a second electrode connected to the second conductivity type semiconductor layer,
wherein the electrode structure comprises a wiring portion and at least one connecting portion, the wiring portion is located above the insulating layer, and the at least one connecting portion is located at an edge of the wiring portion, penetrates through the through hole of the insulating layer, and extends towards the epitaxial layer.

2. The light-emitting element according to claim 1, wherein a horizontal projected area of the wiring portion on the epitaxial layer is greater than a horizontal projected area of the at least one connecting portion on the epitaxial layer.

3. The light-emitting element according to claim 1, wherein a horizontal projection of the wiring portion on the epitaxial layer does not overlap a horizontal projection of the at least one connecting portion on the epitaxial layer.

4. The light-emitting element according to claim 1, wherein the insulating layer is an insulating reflective layer, and the insulating reflective layer is a single-layer structure or a multi-layer structure formed by two layers of materials being repeatedly stacked.

5. The light-emitting element according to claim 1, wherein a horizontal projected area of each electrode structure on the epitaxial layer accounts for 1% to 30% of a horizontal projected area of the epitaxial layer.

6. The light emitting device according to claim 1, further comprising a bonding layer and a substrate, wherein the bonding layer is formed between the substrate and the epitaxial layer for bonding the epitaxial layer to the substrate, and the substrate is a transparent substrate.

7. The light-emitting element according to claim 1, wherein a width of the wiring portion of the electrode structure is between 50 μm and 100 m, a width of the at least one connecting portion is less than the width of the wiring portion, a width of the through hole of the insulating layer is 4 m to 20 m, and the width of the at least one connecting portion is 2 μm to 10 μm larger than the width of the through hole of the insulating layer.

8. The light-emitting element according to claim 1, wherein a projection of the wiring portion on the epitaxial layer is circular, a projection of the at least one connecting portion of the second electrode on the epitaxial layer is arc-shaped, and the at least one connecting portion of the second electrode is located at the edge of the wiring portion.

9. The light-emitting element according to claim 1, wherein current spreading layers connected to the at least one connecting portion are also formed above the epitaxial layer, the current spreading layers are linearly distributed above the epitaxial layer, and a horizontal projection of each of the current spreading layers on the epitaxial layer does not overlap a horizontal projection of the wiring portion on the epitaxial layer.

10. The light-emitting element according to claim 9, wherein an ohmic contact layer is also formed on the second conductivity type semiconductor layer, and the ohmic contact layer is located below the current spreading layers and does not overlap the wiring portion of the second electrode.

11. The light-emitting element according to claim 10, wherein the ohmic contact layer does not overlap the at least one connecting portion of the second electrode.

12. The light-emitting element according to claim 9, wherein an ohmic contact layer is also formed on the second conductivity type semiconductor layer, and the ohmic contact layer is located below the current spreading layers and does not overlap the at least one connecting portion of the second electrode.

13. The light-emitting element according to claim 11, wherein the ohmic contact layer has a strip structure, and a length of the ohmic contact layer is less than a length of each of the current spreading layers.

14. A light-emitting device, comprising: a die-bonding substrate and a light-emitting element fixed to the die-bonding substrate, wherein the light-emitting element is the light-emitting element of claim 1.
